(19) United States
(12) Patent Application Publication
(10) Pub. No.: US 2025/0343085 A1
(43) Pub. Date: Nov. 6, 2025

(54) SELECTIVE INSULATION OF FUEL CELL STACK MONITORING AND CONTROLLING DEVICE

(71) Applicant: GM Global Technology Operations LLC, Detroit, MI (US)

(72) Inventors: Tushar P. Khanzode, Bangalore (IN); Ronald Miller, Bloomfield Hills, MI (US); Bhaskara K. Ch, Bangalore (IN); Abhishek Kumar Sahu, Bengaluru (IN)

(21) Appl. No.: 18/652,026

(22) Filed: May 1, 2024

(51) Int. Cl. H01L 23/08; H01L 23/49; H01M 8/2475

(52) U.S. Cl. CPC H01L 23/08; H01L 23/49; H01M 8/2475; H01M 2250/20

(57) ABSTRACT

A fuel cell system includes a housing, a fuel cell inside the housing, and a stack monitoring and controlling device mounted on the housing. The stack monitoring and controlling device includes an enclosure and cover coupled to the enclosure to define a cavity. The cover defines an inner cover surface. The inner cover surface partially defines the cavity. The stack monitoring and controlling device also includes a metal-oxide-semiconductor field-effect transistor field-effect transistor (MOSFET) disposed in the cavity between the enclosure and the cover. The inner cover surface of the cover faces the MOSFET. The MOSFET includes a body and one or more pins protruding from the body. The system also includes an electrical insulator coupled to the inner cover surface. The electrical insulator defines an inner insulator surface facing the MOSFET. The pin is spaced apart from the electrical insulator to define an air gap.

### INTRODUCTION

The present disclosure relates to a selective insulation for a fuel cell stack monitoring and controlling device.

This introduction generally presents the context of the disclosure. Work of the presently named inventors, to the extent it is described in this introduction, as well as aspects of the description that may not otherwise qualify as prior art at the time of filing, are neither expressly nor impliedly admitted as prior art against this disclosure.

Some vehicle systems use fuel cell systems for propulsion. Fuel cell systems include a stack monitoring and controlling device (SMCD). The SMCD includes a printed circuit board, sensors, bus bars, a cold plate, and power electronic devices disposed inside a casing. The SMCD is mounted on the stack housing inside a fuel cell power module. Some of the high-level functions of the casing are preventing unintended access to power path, protecting electronic devices, electrical isolation of components, shielding from external intrusions, and transfer heat to low temperature coolant loop. To meet the grounding requirements, the SMCD case should be electrically connected to the chassis of the vehicle.

For high voltage clearance, the length of the air gap between an electrical conductor (e.g., pin of the MOSFET) and the SMCD cover should be greater than 3.0 mm. It is therefore desirable to develop a system that electrically isolates the SMCD cover from a high-voltage electrical conductor, such as the pin of the MOSFET.

### SUMMARY

The present disclosure describes a fuel cell system. In an aspect of the present disclosure, the fuel cell system includes a housing, a large number of single fuel cells stacked together inside the housing, and a stack monitoring and controlling device mounted on the housing. The stack monitoring and controlling device includes an enclosure and cover coupled to the enclosure to define a cavity. The cover defines an inner cover surface. The inner cover surface partially defines the cavity. The stack monitoring and controlling device also includes an electronic component, such as a metal-oxide-semiconductor field-effect transistor field-effect transistor (MOSFET), disposed in the cavity between the enclosure and the cover. The inner cover surface of the cover faces the electronic component. The electronic component includes a body (e.g., a p-type substrate) and one or more pins protruding from the body. The system also includes an electrical insulator coupled to the inner cover surface. The electrical insulator defines an inner insulator surface facing the electronic component. The pin is spaced apart from the electrical insulator to define an air gap.

In some aspect of the present disclosure, the electrical insulator is disposed over the pin of the MOSFET. The electrical insulator may be wholly made of polytetrafluoroethylene (PTFE). The cover and the enclosure may each be wholly made of a metallic material. The cover defines a recess at least partly defined by the inner cover surface. The electrical insulator may be entirely disposed in the recess. The inner insulator surface may be flushed with the inner cover surface. The air gap has a gap length defined from the pin to the inner insulator surface. The gap length is greater than 3.0 millimeters (e.g., 3.1 millimeters). The electrical insulator has an insulator thickness. The insulator thickness is between 0.2 millimeters and 1 millimeters (e.g., 0.3 millimeters). The electrical insulator has a dielectric strength. The dielectric strength of the electrical insulator is between 9 kV/mm and 280 kV/mm (e.g., 9 kV/mm). The electrical insulator may be partly or wholly made of a ceramic and/or a polymeric material (e.g., polytetrafluoroethylene (PTFE). The electrical insulator may be entirely disposed in the recess. The cover may be wholly or partly made of an aluminum alloy. The electrical insulator may be wholly or partly wholly made of an elastomer and/or a vitreous enamel.

The inner cover surface has an oblique surface portion and a horizontal surface portion. The horizontal surface portion is elongated along a horizontal direction. The horizontal direction is perpendicular to a vertical direction V. The pin of the MOSFET is spaced apart from the electrical insulator along the vertical direction. The oblique surface portion is obliquely angled relative to the horizontal surface portion. The gap length is defined from the pin of the MOSFET to the inner insulator surface of the electrical insulator along a length axis. The length axis intersects the oblique surface portion at a perpendicular angle. The gap length is parallel to the length axis. An angle is defined from the vertical direction V to the length axis 58, the angle is oblique (e.g., 37 degrees).

Further areas of applicability of the present disclosure will become apparent from the detailed description provided below. It should be understood that the detailed description and specific examples are intended for purposes of illustration only and are not intended to limit the scope of the disclosure.

The above features and advantages, and other features and advantages, of the presently disclosed system and method are readily apparent from the detailed description, including the claims, and exemplary embodiments when taken in connection with the accompanying drawings.

### BRIEF DESCRIPTION OF THE DRAWINGS

The present disclosure will become more fully understood from the detailed description and the accompanying drawings, wherein:

FIG. 1 is a schematic diagram of a vehicle including a fuel cell system.

FIG. 2 is a schematic isometric view of the fuel cell system of FIG. 1, wherein the fuel cell system includes a stack monitoring and controlling device (SMCD).

FIG. 3 is a schematic bottom view of the cover of the SMCD of FIG. 2.

FIG. 4 is an enlarged, bottom view of the cover of the SMCD of FIG. 3, taken around area A of FIG. 3.

FIG. 5 is a schematic cross-sectional view of the SMCD of FIG. 2, taken along section line 5-5 of FIG. 2.

FIG. 6 is a schematic, enlarged cross-sectional view of the SMCD of FIG. 2, taken around area B of FIG. 5.

### DETAILED DESCRIPTION

Reference will now be made in detail to several examples of the disclosure that are illustrated in accompanying drawings. Whenever possible, the same or similar reference numerals are used in the drawings and the description to refer to the same or like parts or steps.

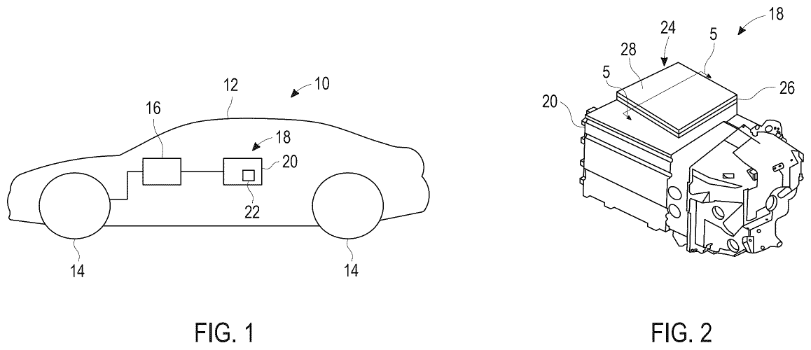

With reference to FIG. 1, a vehicle 10 generally includes a vehicle body 12 and a plurality of wheels 14 coupled to the vehicle body 12. The vehicle 10 may be an autonomous vehicle. In the depicted embodiment, the vehicle 10 may be a sedan, a truck, a coupe, a sport utility vehicle (SUV), a recreational vehicles (RV). The vehicle 10 further includes an electric motor 16 coupled to one or more of the wheels 14. The electric motor 16 is configured to convert electrical energy to mechanical energy (e.g., torque) to drive the wheels 14. The vehicle 10 further includes a fuel cell system 18 electrically connected to the electric motor 16. The fuel cell system 18 is configured to generate electricity from hydrogen or other fuels. Therefore, the fuel cell system 18 provides electricity to the electric motor 16. The fuel cell system 18 includes a housing 20 and one or more fuel cells 22 inside the housing 20.

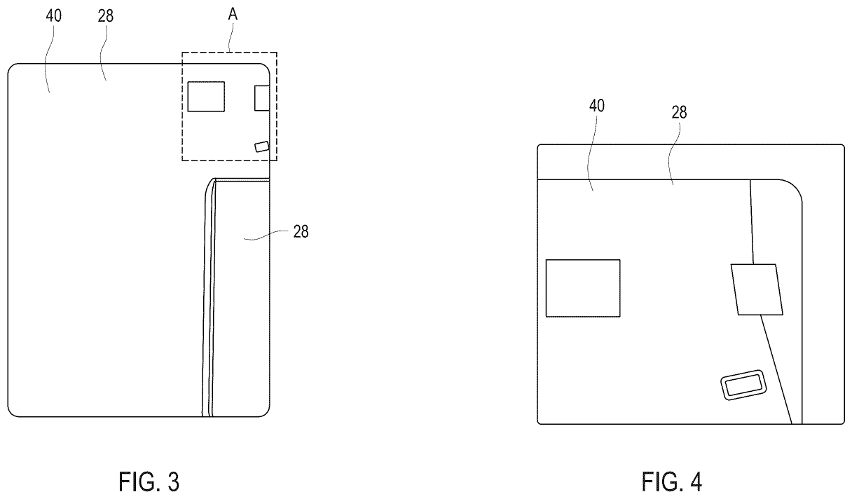

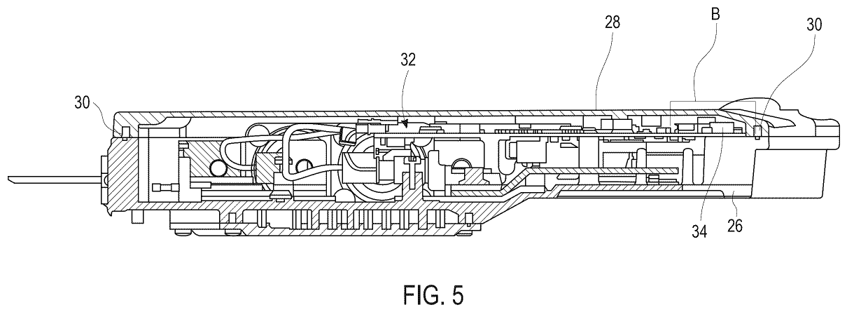

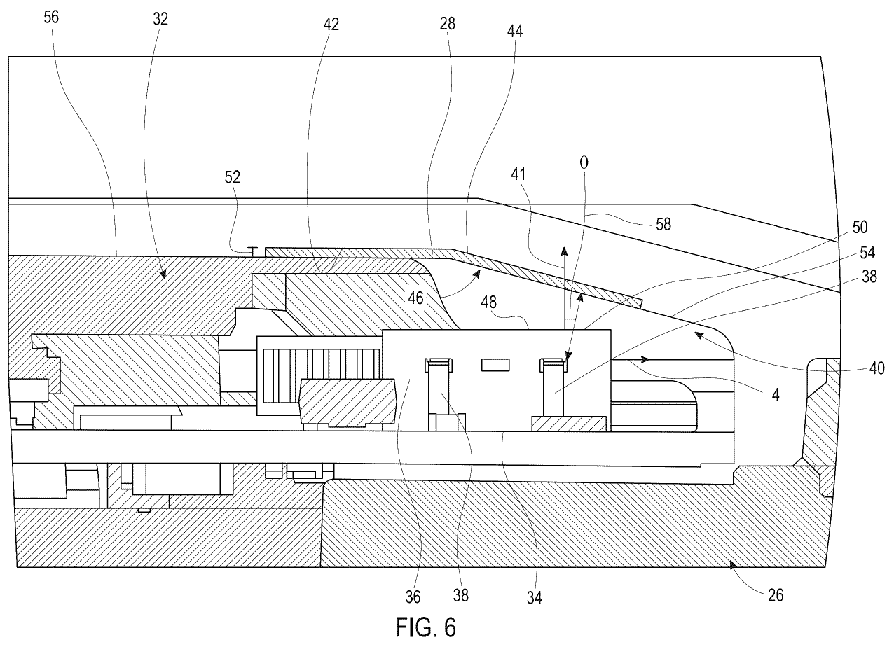

With reference to FIGS. 2-6, the fuel cell system 18 includes a stack monitoring and controlling device (SMCD) 24 mounted on the housing 20. The SMCD 24 includes an enclosure 26 and a cover 28 directly coupled to the enclosure 26. One or more seals 30 that seals the enclosure 26 and cover 28. The enclosure 26 and the cover 28 collectively define a cavity 32. The SMCD 24 houses a printed circuit board, sensors, bus bars, a cold plate, and power electronic devices in the cavity 32. The cover 28 and the enclosure 26 are each partly or wholly made of a metallic material to enhance the structural integrity of the SMCD 24. For example, the cover 28 may be partially or wholly made of an aluminum alloy.

The SMCD 24 includes an electronic component, such as a metal-oxide-semiconductor field-effect transistor (MOSFET) 34, a switch, a rely, a capacitor, among others, in the cavity 32 between the enclosure 26 and the cover 28. The MOSFET 34 or other electronic component includes a body 36 (e.g., a p-type substrate or a n-type substrate) and one or more pins 38 protruding from the body 36. The pin 38 is wholly made of an electrically conducting material and carries high-voltage electricity. It is therefore desirable to electrically isolate the pin 38 from the cover 28 to prevent short circuits.

The cover 28 defines an inner cover surface 40 that partially defines the cavity 32. The inner cover surface 40 faces the MOSFET 34 or other electronic component. The cover 28 defines a recess 42 at least partly defined by the inner cover surface 40. The SMCD 24 includes an electrical insulator 44 coupled to the inner cover surface 40 to prevent electricity from traveling from the pin 38 of the MOSFET 34 (or other electronic component) to the cover 28. The electrical insulator 44 may be entirely disposed in the recess 42.

The electrical insulator 44 defines an inner insulator surface 46 facing the MOSFET 34 or other electronic component. The inner insulator surface 46 is flushed with the inner cover surface 40. The pin 38 is spaced apart from the electrical insulator 44 to define an air gap 48. The pin 38 is spaced apart from the electrical insulator 44 along a vertical direction V. Accordingly, the electrical insulator 44 is disposed over the pin 38 of the MOSFET 34. The electrical insulator 44 is partly or wholly made of an electrically insulating material, such as a polymeric material, a ceramic, and/or a vitreous enamel, to electrically isolate the cover 28 from the pin 38 of the MOSFET 34 or other electronic component. As non-limiting examples, the electrical isolator 44 may be wholly or partly made of an elastomer and/or polytetrafluoroethylene (PTFE) to electrically isolate the cover 28 from the pin 38 of the MOSFET 34.

As mentioned above, the pin 38 of the MOSFET 34 (or other electronic component) is spaced apart from the electrical insulator 44 to define the air gap 48. The air gap 48 has a gap length 50 defined from the pin 38 of the MOSFET 34 (or other electronic component) to the inner insulator surface 46 of the electrical insulator 44. The gap length 50 is greater than 3.0 millimeters (e.g., 3.1 millimeters) to prevent electricity from traveling from the pin 38 of the MOSFET 34 (or other electronic component) to the cover 28, thereby preventing short circuits. The electrical insulator 44 has an insulator thickness 52. The insulator thickness 52 is between 0.2 millimeters and 1 millimeters (e.g., 0.3 millimeters) to prevent electricity from traveling from the pin 38 of the MOSFET 34 (or other electronic component) to the cover 28, thereby preventing short circuits. The electrical insulator 44 has a dielectric strength. The dielectric strength of the electrical insulator 44 is between 9 kV/mm and 280 kV/mm (e.g., 9 kV/mm) to prevent electricity from traveling from the pin 38 of the MOSFET 34 (or other electronic component) to the cover 28, thereby preventing short circuits.

The inner cover surface 40 has an oblique surface portion 54 and a horizontal surface portion 56. The horizontal surface portion 56 is elongated along a horizontal direction H. The horizontal direction H is perpendicular to the vertical direction V. The oblique surface portion 54 is obliquely angled relative to the horizontal surface portion 56. The gap length 50 is defined from the pin 38 of the MOSFET 34 (or other electronic component) to the inner insulator surface 46 of the electrical insulator 44 along a length axis 58. The length axis 58 intersects the oblique surface portion 54 at a perpendicular angle. The gap length 50 is parallel to the length axis 58. An angle θ is defined from the vertical direction V to the length axis 58. The angle θ is oblique (e.g., 37 degrees).

The electrical insulator 44 electrically isolates the pin 38 of the MOSFET 34 (or other electronic component) with minimal changes, without affecting the manufacturing procedure and cost. The electrical insulator 44 is partly or wholly made of an electrically insulating and excellent dielectric strength material at the shorting prone regions in the SMCD 24. Manufacturing the SMCD 24 includes selective machining of the cover 28 (e.g., rectangular patches of varying length and width, orientation based on the electrical isolation needed location). Further, manufacturing the SMCD 24 includes filling and/or coating the machined patches with a superior electrical insulator 44. Manufacturing the SMCD 24 further includes achieving excellent bonding (e.g., curing) between the insulator 44 and cover 28 that retains throughout the life of SMCD 24 subjected to harsh environmental, thermal, and mechanical conditions. As discussed above, the electrical insulator materials may be ceramics, polymers, elastomers, and enamels. For instance, PTFE may be used for the electrical insulator 44 for its distinguishable properties (i.e., outstanding electrical insulation, durable, stable at extreme temperatures, chemically inert, strong bonding with Aluminum), cost, availability, and easy to work with).

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the presently disclosed system and method that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

The drawings are in simplified form and are not to precise scale. For purposes of convenience and clarity only, directional terms such as top, bottom, left, right, up, over, above, below, beneath, rear, and front, may be used with respect to the drawings. These and similar directional terms are not to be construed to limit the scope of the disclosure in any manner.

Embodiments of the present disclosure are described herein. It is to be understood, however, that the disclosed embodiments are merely examples and other embodiments can take various and alternative forms. The figures are not necessarily to scale; some features could be exaggerated or minimized to display details of particular components. Therefore, specific structural and functional details disclosed herein are not to be interpreted as limiting, but merely as a representative basis for teaching one skilled in the art to variously employ the presently disclosed system and method. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

This description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A fuel cell system, comprising:
a housing;
a fuel cell inside the housing;
a stack monitoring and controlling device mounted on the housing, wherein the stack monitoring and controlling device includes:
an enclosure;
a cover coupled to the enclosure to define a cavity, wherein the cover defines an inner cover surface, and the inner cover surface partially defines the cavity;
an electronic component disposed in the cavity between the enclosure and the cover, wherein the inner cover surface of the cover faces the electronic component, the electronic component includes:
a body; and
a pin protruding from the body; and
an electrical insulator coupled to the inner cover surface, the electrical insulator defines an inner insulator surface facing the electronic component, and the pin is spaced apart from the electrical insulator to define an air gap.

2. The fuel cell system of claim 1, wherein the electronic component is a metal-oxide-semiconductor field-effect transistor (MOSFET), and the electrical insulator is disposed over the pin of the MOSFET.

3. The fuel cell system of claim 1, the electrical insulator is wholly made of Polytetrafluoroethylene (PTFE).

4. The fuel cell system of claim 1, wherein each of the cover and the enclosure is wholly made of a metallic material, and the cover defines a recess at least partly defined by the inner cover surface, and the electrical insulator is entirely disposed in the recess.

5. The fuel cell system of claim 1, wherein the inner insulator surface is flushed with the inner cover surface.

6. The fuel cell system of claim 1, wherein the air gap has a gap length defined from the pin to the inner insulator surface, and the gap length is greater than 3.0 millimeters.

7. The fuel cell system of claim 6, wherein the electrical insulator has an insulator thickness, and the insulator thickness is between 0.2 millimeters and 1 millimeters.

8. The fuel cell system of claim 7, wherein the electrical insulator has a dielectric strength, and the dielectric strength is between 9 kV/mm and 280 kV/mm.

9. The fuel cell system of claim 8, wherein the electrical insulator is wholly made of a ceramic.

10. The fuel cell system of claim 8, wherein the electrical insulator is wholly made of a polymeric material.

11. The fuel cell system of claim 8, wherein the electronic component is a metal-oxide-semiconductor field-effect transistor (MOSFET), the electrical insulator is wholly made of Polytetrafluoroethylene (PTFE), the air gap has a gap length defined from the pin to the inner insulator surface, the gap length is 3.1 millimeters, the electrical insulator has an insulator thickness, the insulator thickness is 0.3 millimeters, the electrical insulator has a dielectric strength, the dielectric strength is 9 kV/mm, the inner insulator surface is flushed with the inner cover surface, the cover defines a recess at least partly by the inner cover surface, the electrical insulator is entirely disposed in the recess, the cover is wholly made of an aluminum alloy, the cover defines a recess at least partly defined by into the inner cover surface, the electrical insulator is entirely disposed in the recess, the inner cover surface has an oblique surface portion and a horizontal surface portion, the horizontal surface portion is elongated along a horizontal direction, the horizontal direction is perpendicular to a vertical direction V, the pin of the MOSFET is spaced apart from the electrical insulator along the vertical direction, the oblique surface portion is obliquely angled relative to the horizontal surface portion, the gap length is defined from the pin of the MOSFET to the inner insulator surface of the electrical insulator along a length axis, the length axis intersects the oblique surface portion at a perpendicular angle, the gap length is parallel to the length axis, an angle is defined from the vertical direction V to the length axis, the angle is oblique, and the angle is 37 degrees.

12. The fuel cell system of claim 1, wherein the electrical insulator is wholly made of an elastomer.

13. The fuel cell system of claim 1, wherein the electrical insulator is wholly made of a vitreous enamel.

14. A stack monitoring and controlling device, comprising:
an enclosure;
a cover coupled to the enclosure to define a cavity, wherein the cover defines an inner cover surface, and the inner cover surface partially defines the cavity
a metal-oxide-semiconductor field-effect transistor (MOSFET) disposed in the cavity between the enclosure and the cover, wherein the inner cover surface of the cover faces the MOSFET, the MOSFET includes:
a body; and
a pin protruding from the body; and
an electrical insulator coupled to the inner cover surface, the electrical insulator defines an inner insulator surface facing the MOSFET, and the pin is spaced apart from the electrical insulator to define an air gap.

15. The stack monitoring and controlling device of claim 14, wherein the electrical insulator is disposed over the pin of the MOSFET.

16. The stack monitoring and controlling device of claim 14, the electrical insulator is wholly made of Polytetrafluoroethylene (PTFE.

17. The stack monitoring and controlling device of claim 14, wherein each of the cover and the enclosure is wholly made of a metallic material, and the cover defines a recess at least partly defined by the inner cover surface.

18. The stack monitoring and controlling device of claim 14, wherein the inner insulator surface is flushed with the inner cover surface.

19. The stack monitoring and controlling device of claim 14, wherein the air gap has a gap length defined from the pin to the inner insulator surface.

20. A vehicle, comprising:
a plurality of wheels;
an electric motor coupled to the plurality of wheels;
a fuel cell system electrically connected to the electric motor, wherein the fuel cell system includes:
a housing;
a fuel cell inside the housing;
a stack monitoring and controlling device mounted on the housing, wherein the stack monitoring and controlling device includes:
an enclosure, wherein the enclosure is wholly made of a metallic material;
a cover coupled to the enclosure to define a cavity, wherein the cover defines an inner cover surface, and the inner cover surface partially defines the cavity, the cover made is wholly made of an aluminum alloy, the cover is directly coupled to the enclosure, and the cover defines a recess at least partly defined into the inner cover surface;
a metal-oxide-semiconductor field-effect transistor (MOSFET) disposed in the cavity between the enclosure and the cover, wherein the inner cover surface of the cover faces the MOSFET, the MOSFET includes:
a body; and
a pin protruding from the body; and
an electrical insulator attached to the inner cover surface, the electrical insulator is disposed over the pin of the MOSFET, the electrical insulator is wholly made of Polytetrafluoroethylene (PTFE), the electrical insulator is entirely disposed in the recess, the electrical insulator defines an inner insulator surface facing the MOSFET, the inner insulator surface is flushed with the inner cover surface, and the pin is spaced apart from the electrical insulator to define an air gap, the air gap has a gap length defined from the pin to the inner insulator surface, the gap length is greater than 3.0 millimeters, the electrical insulator has an insulator thickness, the insulator thickness is between 0.2 millimeters and 1 millimeters, the electrical insulator has a dielectric strength, and the dielectric strength is between 9 kV/mm and 280 kV/mm.
